(19) United States
(12) Patent Application Publication
(10) Pub. No.: US 2023/0155076 A1
(43) Pub. Date: May 18, 2023

(54) QUANTUM DOT FILM, MANUFACTURING METHOD THEREOF, AND DISPLAY PANEL

(71) Applicant: Huizhou China Star Opeoelectronics Technology Co., Ltd, Huizhou (CN)

(72) Inventor: Linlin FU, Huizhou (CN)

(21) Appl. No.: 17/287,537

(22) PCT Filed: Mar. 31, 2021
(86) PCT No.: PCT/CN2021/084459

§ 371 Date: Apr. 22, 2021

(30) Foreign Application Priority Data
Mar. 25, 2021 (CN) 20210319559.0

(51) Int. Cl. H01L 33/50; G02F 1/1335; G02F 1/13357

(52) U.S. Cl. CPC H01L 33/505; G02F 1/133614; G02F 1/133603; H01L 2933/0041

(57) ABSTRACT

A quantum dot film, a manufacturing method thereof, and a display panel are provided. In the quantum dot film, grooves are defined on a first protective layer and/or a second protective layer corresponding to each quantum dot region. Quantum dot layers are filled in the grooves to form protruding structures. Therefore, the quantum dot layers of each quantum dot region are made to have height differences to reduce optical path differences of different lights at different angles passing through the quantum dot layers to ease a problem of uneven display existing in display products.

### BACKGROUND OF INVENTION

### Field of Invention

The present disclosure relates to the field of display technology and particularly to a quantum dot film, a manufacturing method thereof, and a display panel.

### Description of Prior Art

With development of display technology and consumers' higher requirements for product display quality, high color gamut display products are becoming more and more favored by consumers. There are many ways to realize high color gamut, which mainly include using light emitting diode (LED) chips, fluorescent powders, or integration of quantum dots (QDs) with different components, such as QD-LED, etc. A basic principle thereof is to make a half-peak width of a spectrum of backlights narrow to improve color purity, so the color gamut is improved. Wherein, using quantum dot films (QD film) is a main implementation solution of most current high color gamut liquid crystal display (LCD) devices.

However, regarding display products using LEDs as light sources, because a light shape of the LED is a Lambertian type, a light intensity at middle angles is strong, and light at large angles is weak. Furthermore, light at the middle angles directly passes through the quantum dot film with short optical paths and little excitation, and the light at the large angles passes through the quantum dot film with long optical paths and great excitation. Therefore, this causes light extractions of the light at the middle angles and the large angles after passing through the quantum dot film to be different, and a phenomenon of uneven display appears.

Therefore, a technical problem of uneven display existing in current display products needs to be solved.

### SUMMARY OF INVENTION

The present disclosure provides a quantum dot film, a manufacturing method thereof, and a display panel to ease the technical problem of uneven display existing on current display products.

In order to solve the problems mentioned above, the present disclosure provides the technical solutions as follows:

One embodiment of the present disclosure provides a quantum dot film divided into a plurality of quantum dot regions. The quantum dot film includes:

quantum dot layers, wherein quantum dots are disposed on the quantum dot layers; and

a first protective layer and a second protective layer disposed on two opposite sides of the quantum dot layers,

wherein the quantum dot layers of each of the quantum dot regions have height differences to reduce optical path differences between lights of different incident angles passing through the quantum dot layer.

In the quantum dot film provided by one embodiment of the present disclosure, the quantum dot layers of the quantum dot regions have protruding structures.

In the quantum dot film provided by one embodiment of the present disclosure, first grooves are defined on one of the first protective layer or the second protective layer corresponding to the quantum dot regions, the protruding structures are filled in the first grooves.

In the quantum dot film provided by one embodiment of the present disclosure, the second grooves and third grooves are defined where the first protective layer and the second protective layer correspond to the quantum dot regions, and the protruding structures are filled in the second grooves and the third grooves.

In the quantum dot film provided by one embodiment of the present disclosure, the second grooves are defined opposite to the third grooves.

In the quantum dot film provided by one embodiment of the present disclosure, a sum of a depth of the second grooves and a depth of the third grooves is equal to a separation distance between the first protective layer and the second protective layer.

In the quantum dot film provided by one embodiment of the present disclosure, the depth of the second grooves is equal to the depth of the third grooves.

In the quantum dot film provided by one embodiment of the present disclosure, a gap is formed between one of the first protective layer or the second protective layer and a part of the quantum dot layers in the quantum dot regions.

In the quantum dot film provided by one embodiment of the present disclosure, a shape of a cross section of the protruding structures includes rectangular, arc, triangular, or trapezoidal.

In the quantum dot film provided by one embodiment of the present disclosure, the quantum dots of different quantum dot regions are same, and the quantum dots include red quantum dots and green quantum dots.

In the quantum dot film provided by one embodiment of the present disclosure, a particle size of the red quantum dots is greater than a particle size of the green quantum dots.

In the quantum dot film provided by one embodiment of the present disclosure, concentrations of the quantum dots are in positive correlation with heights of the quantum dot layers.

In the quantum dot film provided by one embodiment of the present disclosure, the quantum dot film further includes black matrices, the quantum dot layers are divided into the plurality of quantum dot regions by the black matrices, and the quantum dots in each two adjacent quantum dot regions are different.

One embodiment of the present disclosure further provides a display panel, including a quantum dot film and a plurality of excited light sources, wherein each quantum dot region corresponds to one of the excited light sources, the quantum dot film is divided into a plurality of quantum dot regions, and the quantum dot film includes:

quantum dot layers, wherein quantum dots are disposed on the quantum dot layers; and

a first protective layer and a second protective layer disposed on two opposite sides of the quantum dot layers,

wherein the quantum dot layers of each of the quantum dot regions have height differences to reduce optical path differences between lights of different incident angles passing through the quantum dot layers.

In the display panel provided by one embodiment of the present disclosure, the quantum dot layers of the quantum dot regions have protruding structures.

In the display panel provided by one embodiment of the present disclosure, a shape of a cross section of the protruding structures includes rectangular, arc, triangular, or trapezoidal.

In the display panel provided by one embodiment of the present disclosure, the excited light sources are blue light emitting diodes (LEDs).

One embodiment of the present disclosure further provides a manufacturing method of a quantum dot film, including:

manufacturing a first protective layer, wherein manufacturing the first protective layer includes providing a base material layer and manufacturing a barrier layer on the base material layer to form the first protective layer;

patterning the first protective layer to form first grooves;

manufacturing quantum dot layers, wherein manufacturing the quantum dot layers includes manufacturing the quantum dot layers on the first protective layer and the first grooves to make the quantum dot layers form the protruding structures; and

manufacturing a second protective layer on the quantum dot layers to form the quantum dot film.

In the manufacturing method of the quantum dot film provided by one embodiment of the present disclosure, the step of manufacturing the quantum dot layers on the first protective layer and the first groove to make the quantum dot layers form the protruding structures includes:

dispersing the quantum dots in a macromolecule polymer solution to form a quantum dot glue solution;

spraying the quantum dot glue solution on the first protective layer and the first grooves by a spraying process; and

performing a pre-curing process on the sprayed quantum dot glue solution to form the quantum dot layers.

In the manufacturing method of the quantum dot film provided by one embodiment of the present disclosure, ultraviolet light irradiation, heating, evaporating solvents, or adding curing agent is adopted in the pre-curing process.

In the quantum dot film, the manufacturing method thereof, and the display panel provided by the present disclosure, the quantum dot film is divided into the plurality of quantum dot regions, and the quantum dot film includes the quantum dot layers and the first protective layer and the second protective layer disposed on two opposite sides of the quantum dot layers; the grooves are defined on the first protective layer and/or the second protective layer corresponding to each quantum dot region; and the quantum dot layers are filled in the grooves to form the protruding structures. Therefore, the quantum dot layers of each quantum dot region are made to have height differences to reduce optical path differences of different lights at different angles passing through the quantum dot layers, and extents of the lights at different angles passing through the quantum dot layers are excited similarly, which prevents appearance of uneven display.

### DESCRIPTION OF DRAWINGS

In order to more clearly illustrate embodiments or the technical solutions of the present disclosure, the accompanying figures of the present disclosure required for illustrating embodiments or the technical solutions of the present disclosure will be described in brief. Obviously, the accompanying figures described below are only part of the embodiments of the present disclosure, from which those skilled in the art can derive further figures without making any inventive efforts.

FIG. 1 is a schematic diagram of a cross-sectional structure of a quantum dot film provided by one embodiment of the present disclosure.

FIG. 2 is a schematic diagram of details of protective layers provided by one embodiment of the present disclosure.

FIG. 3 is a schematic diagram of contrasting relations of quantum dot regions and excited light sources provided by one embodiment of the present disclosure.

FIG. 4 is a schematic diagram of a principle of implementation of reducing optical path difference provided by one embodiment of the present disclosure.

FIG. 5 is a schematic diagram of another cross-sectional structure of the quantum dot film provided by one embodiment of the present disclosure.

FIG. 6 is a schematic diagram of yet another cross-sectional structure of the quantum dot film provided by one embodiment of the present disclosure.

FIG. 7 is a schematic diagram of still another cross-sectional structure of the quantum dot film provided by one embodiment of the present disclosure.

FIG. 8 is a schematic diagram of a cross-sectional structure of a display panel provided by one embodiment of the present disclosure.

FIG. 9 is a schematic diagram of another cross-sectional structure of the display panel provided by one embodiment of the present disclosure.

FIG. 10 is a flowchart of a manufacturing method of the quantum dot film provided by one embodiment of the present disclosure.

### DETAILED DESCRIPTION OF EMBODIMENTS

The descriptions of embodiments below refer to accompanying drawings in order to illustrate certain embodiments which the present disclosure can implement. The directional terms of which the present disclosure mentions, for example, “top”, “bottom”, “upper”, “lower”, “front”, “rear”, “left”, “right”, “inside”, “outside”, “side”, etc., only refer to directions of the accompanying figures. Therefore, the used directional terms are for illustrating and understanding the present disclosure, but not for limiting the present disclosure. In the figures, units with similar structures are used same labels to indicate. In the drawings, the thicknesses of layers and regions are exaggerated for clarity. The dimensions and thickness of each component shown in the accompanying figures are arbitrarily shown, present disclosure is not limited thereto.

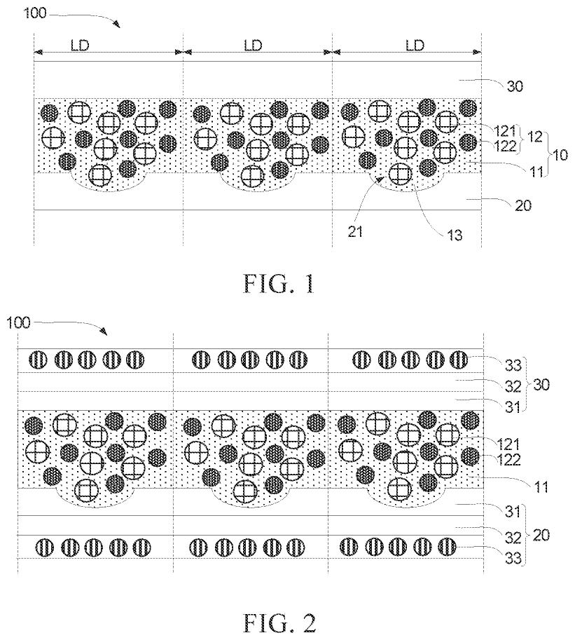

Please refer to FIG. 1. FIG. 1 is a schematic diagram of a cross-sectional structure of a quantum dot film provided by one embodiment of the present disclosure. The quantum dot film 100 is divided into a plurality of quantum dot regions LD. The quantum dot film 100 includes quantum dot layers 10 and a first protective layer 20 and a second protective layer 30 disposed on two opposite sides of the quantum dot layer 10. Quantum dots 12 are disposed on the quantum dot layers 10. Wherein, the quantum dot layers 10 of each of the quantum dot regions LD have height differences to reduce optical path differences between lights of different incident angles passing through the quantum dot layers 10.

In this embodiment, the quantum dot layers 10 of each quantum dot region LD have height differences to reduce optical path differences of different lights at different angles passing through the quantum dot layers 10 to make levels of the lights at different angles passing through the quantum dot layers 10 be excited similarly, which prevents occurrences of uneven display.

Specifically, please continue referring to FIG. 1. A middle layer of the quantum dot film 100 is the quantum dot layers 10. The quantum dot layers 10 include a macromolecule polymer base material 11 and the quantum dots 12 uniformly dispersed in the macromolecule polymer base material 11.

The quantum dots 12 are core-shell structures constituted by a semiconductor material and include quantum-dot central cores and outer shells. Materials of the quantum dots 12 include one or more of magnesium sulfide (MgS), cadmium telluride (CdTe), cadmium selenide (CdSe), cadmium sulfide (CdS), cadmium zinc sulfide (CdZnS), zinc selenide (ZnSe), zinc telluride (ZnTe), zinc sulfide (ZnS), zinc oxide (ZnO), gallium arsenide (GaAs), gallium nitride (GaN), gallium phosphide (GaP), indium phosphide (InP), indium arsenide (InAs), indium nitride (InN), indium antimonide (InSb), aluminium phosphide (AlP), or aluminium antimonide (AlSb), etc. For example, the central core is a CdSe core, and the outer shell is a ZnS shell. Particle sizes of the quantum dots 12 are generally about 10 nanometers. Due to difference in sizes of the quantum dots, wavelengths of emitted lights from the quantum dots 12 vary with the particle sizes and compositions.

Furthermore, as a photoluminescent material, the quantum dots 12 can convert absorbed lights with short wavelength into light with long wavelength. In order to obtain the quantum dot film 100 of a predetermined color, the quantum dots 12 in the quantum layers may include one type or more types. For example, in one embodiment of the present disclosure, in order to obtain white light, the quantum dots 12 of the quantum dot layers 10 include red quantum dots 121 and green quantum dots 122, particle sizes of the green quantum dots 122 are smaller, and particle sizes of the red quantum dots 121 are larger. The red quantum dots 121 are excited by light to emit red light, and the green quantum dots 122 are excited by light to emit green light. At the same time, blue light is used as excitation light sources, such as blue light emitting diodes (LEDs), etc. The blue light emitted from the blue light sources is converted into red light and green light by the quantum dot film 100, and the red light, green light, and blue light are mixed to obtain white light.

Of course, the quantum dots 12 of the present disclosure are not limited to the quantum dots that emit red light and green light, and quantum dots that emit any wavelength within a visible light wavelength range are further included. Specifically, they can be configured according to a quantum dot film 100 of a predetermined color that needs to be obtained.

The quantum dots 12 are uniformly dispersed in the macromolecule polymer base material 11. Specifically, the quantum dot layers 10 can be formed by uniformly dispersing the quantum dots 12 in a macromolecule polymer solution and then curing. The macromolecule polymer solution is formed by doping macromolecule polymer in an organic solvent. The macromolecule polymer includes one or more of macromolecule polymers such as silicone resin, epoxy resin, polyacrylamide, acrylic resin, photocuring resin, heat curing resin, etc. For example, the macromolecule polymer base material 11 can be polyethylene terephthalate (PET) or triacetate cellulose (TAC), etc.

Furthermore, the first protective layer 20 and the second protective layer 30 are disposed on two opposite sides of the quantum dot layers 10. Optionally, the first protective layer 20 is disposed on a lower surface of the quantum dot layer 10, and the second protective layer 30 is disposed on an upper surface of the quantum dot layer 10. Wherein, the upper surface of the quantum dot layer 10 refers to a light exiting surface of the quantum dot layer 10, and the lower surface of the quantum dot layer 10 refers to a light incident surface of the quantum dot layer 10, i.e., a surface illuminated by the excitation light sources. The first protective layer 20 and the second protective layer 30 are configured to protect stability of structures of the quantum dot layers 10 and can prevent failure of the quantum dots 12 incurred by intrusion of water and oxygen into the quantum dot layer 10 at the same time.

Optionally, please refer to FIG. 2. FIG. 2 is a schematic diagram of details of protective layers provided by one embodiment of the present disclosure. The first protective layer 20 and the second protective layer 30 both include a base material layer 31, a barrier layer 32, etc., which are laminated. The barrier layer 32 is disposed on one side of the base material layer 31 away from the quantum dot layers 10. The base material layer 31 can be polyethylene terephthalate, etc., and inorganic materials with strong water and oxygen barrier ability can be adopted for the barrier layer 32. The dense arrangement of the inorganic materials at the atomic level can effectively block moisture and oxygen. For example, the inorganic material includes at least one of aluminum nitride, aluminum oxynitride, titanium nitride, titanium oxynitride, zirconium nitride, zirconium oxynitride, silicon oxide, silicon nitride, silicon oxynitride, graphene, etc.

Of course, the first protective layer 20 and the second protective layer 30 can further include a diffusion layer 33 disposed on one side of the barrier layer 32 away from the base material layer 31 to improve uniformity of the light.

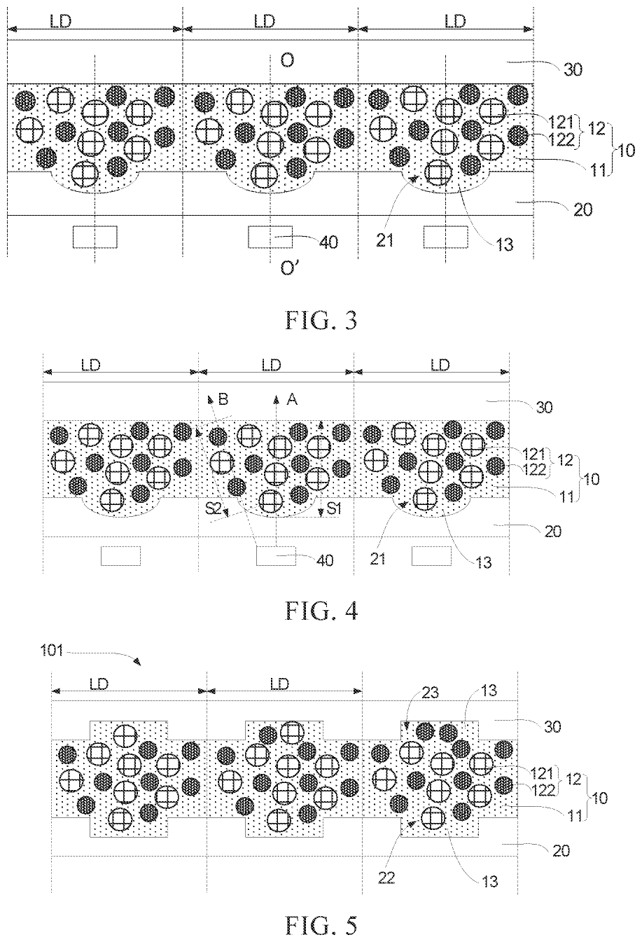

The first protective layer 20, the second protective layer 30, and the quantum dot layers 10 together form the quantum dot film 100. The quantum dot film 100 is divided into the plurality of quantum dot regions LD. The quantum dots 12 disposed on the quantum dot layers 10 in different quantum dot regions LD are same. For example, the red quantum dots 121 and the green quantum dots 122 are disposed on the quantum dot layers 10. Therefore, after the light of the excited light sources passes through the quantum dot film 100, outgoing lights of each quantum dot region LD are white lights. Optionally, please refer to FIG. 3. FIG. 3 is a schematic diagram of contrasting relations of the quantum dot regions and the excited light sources provided by one embodiment of the present disclosure. Each of the quantum dot regions LD corresponds to one excited light source 40. For example, one quantum dot region LD corresponds to one blue light LED chip.

Furthermore, the quantum dot layers 10 of each of the quantum dot regions LD have height differences. The height differences can be formed by disposing protruding structures 13 on the corresponding quantum dot layers 10. By disposing the quantum dot layers 10 having the height differences, optical path differences of the lights passing through the quantum dot film 100 are reduced.

Formation of the protruding structures 13 and a principle of reducing the optical path differences of the light passing through the quantum dot film 100 will be described below by combining specific embodiments.

Specifically, the quantum dot layers 10 of the quantum dot regions LD have the protruding structures 13. First grooves 21 are defined on one of the first protective layer 20 or the second protective layer 30. The protruding structures 13 are filled in the first grooves 21, i.e., the quantum dot layers 10 are filled in the first grooves 21 to form the protruding structures 13.

Optionally, in each corresponding quantum dot region LD, the first grooves 21 are defined on the first protective layer 20. A cross-sectional shape of the first grooves 21 is arc, and the present disclosure is not limited thereto. The cross-sectional shape of the first grooves 21 of the present disclosure further includes any one of rectangular, triangular, or trapezoidal, or one of other irregular shapes. In this embodiment, the cross-sectional shape being arc is used as an example for description. The quantum dot layers 10 are filled in the first grooves 21 to form the protruding structures 13, and the cross-sectional shape of the protruding structures 13 is also arc. A radius of curvature of the arc gradually increases from the middle to the two sides. It can be understood that the quantum dot layers 10 are filled in the first grooves 21 to form the protruding structures 13, and then the cross-sectional shape of the protruding structures 13 is same as the cross-sectional shape of the first grooves 21. Furthermore, existence of the protruding structures 13 allows height differences to form between the quantum dot layers 10, thereby reducing optical path differences of lights passing through the quantum dot layers 10.

Specifically, please refer to FIG. 3 and FIG. 4. FIG. 4 is a schematic diagram of a principle of implementation of reducing the optical path difference provided by one embodiment of the present disclosure. In FIG. 4, one excited light source 40 is correspondingly disposed with each of the quantum dot regions LD. A middle section of the protruding structures 13 directly faces the excited light sources 40. Optionally, a center line O-O′ of the protruding structures 13 overlaps a center line of the excited light sources 40. Wherein, the middle section of the protruding structures 13 refers to a part of the protruding structures 13 located at a bottom of the first grooves 21. A thickness of the quantum dot layers 10 corresponding to the part is thickest; i.e., from the middle section of protruding structures 13 to two sides of the protruding structure 13, the thickness of the quantum dot layers 10 gradually decreases.

When the light emitted from the excited light sources 40 passes through the quantum dot layers 10, due to the existence of the protruding structures 13, the optical path differences of the light passing through the quantum dot layers 10 are similar or equal, i.e., the optical path differences of the light passing through the quantum dot layers 10 at different angles can be reduced.

Specifically, as illustrated in FIG. 4, two lights emitted from the excited light sources 40 are illustrated. A first light A is perpendicularly incident on the middle section of the protruding structures 13 of the quantum dot layers 10, i.e., the first light A is incident on a region of the quantum dot layers with a thick thickness. A second light B is incident on an edge section of the protruding structures 13, i.e., the second light B is incident on a region of the quantum dot layers 10 with a little thickness. Wherein, the second light B can be a light close to the excited light sources 40. Therefore, an optical path 51 of the first light A passing through the quantum dot layers 10 is similar to or equal to an optical path S2 of the second light B passing through the quantum dot layers 10, which reduces the optical path difference of the first light A and the second light B passing through the quantum dot layers 10.

Of course, the embodiments of the present disclosure only take reducing the optical path difference between the first light A and the second light B as an example to illustrate the effect of disposing the protruding structures 13 on the quantum dot layers 10. While other lights between the first light A and the second light B change according to the thickness of the quantum dot layers 10, the optical paths of these other lights passing through the quantum dot layers 10 are also similar to or equal to the optical paths of the first light A and the second light B passing through the quantum dot layers 10. In this way, the optical paths of the lights emitted from the excited light sources 40 passing through the quantum dot layers 10 are similar or equal, so that levels of excitation by the quantum dots 12 are similar or same, thus allowing light extraction from the quantum dot film 100 at different viewing angles to be more uniform.

It should be noted that configurations of depths of the first grooves 21 and gradients of the first grooves 21 can be determined specifically according to an actual reduction range of the optical path difference to be achieved, a light extraction angle of the excited light sources 40, a configured thickness of the quantum dot layer 10, or other factors, etc.

In this embodiment, by disposing the arc-shaped first grooves 21 on the first protective layer 20 to make the quantum dot layers 10 form the arc-shaped protruding structures 13, the optical paths of the lights emitted from the excited light sources 40 passing through the quantum dot layers 10 are similar or equal. Therefore, the optical path differences are reduced, and the phenomenon of appearance of uneven display is prevented.

In one embodiment, please refer to FIG. 5. FIG. 5 is a schematic diagram of another cross-sectional structure of the quantum dot film provided by one embodiment of the present disclosure. The difference from the aforesaid embodiments is that the quantum dot film 101 includes the quantum dot layers 10 and the first protective layer 20 and the second protective layer 30 located on opposite sides of the quantum dot layers 10; in each quantum dot region LD, second grooves 22 and third grooves 23 are defined on the first protective layer 20 and the second protective layer 30; and the protruding structures 13 of the quantum dot layers 10 are filled in the second grooves 22 and the third grooves 23, so that a difference in film thickness of the first protective layer 20 and the second protective layer 30 can be balanced.

Specifically, the second grooves 22 are defined opposite to the third grooves 23. Optionally, projections of the second grooves 22 and the third grooves 23 overlap each other in a vertical direction. Cross-sectional shapes of the second grooves 22 and the third grooves 23 are rectangular. Of course, the present disclosure is not limited thereto. The cross-sectional shapes of the second grooves 22 and the third grooves 23 further include any one of arc, triangular, trapezoidal, etc., or one of other irregular shapes. In this embodiment, the cross-sectional shape being rectangular is used as an example for description. The quantum dot layers 10 are filled in the second grooves 22 and the third grooves 23 to respectively form the corresponding protruding structures 13, and the cross-sectional shapes of the protruding structures 13 are also rectangular. It can be understood that the quantum dot layers 10 are filled in the second grooves 22 and the third grooves 23 to respectively form the protruding structures 13, and then the cross-sectional shapes of the protruding structures 13 are same as the cross-sectional shapes of the second grooves 22 and the third grooves 23. Furthermore, existence of the protruding structures 13 allows height differences to form between the quantum dot layers 10, thereby reducing optical path differences of lights passing through the quantum dot layers 10.

Furthermore, a sum of a depth of the second grooves 22 and a depth of the third grooves 23 is equal to a separation distance between the first protective layer 20 and the second protective layer 30. Optionally, the depth of the second grooves 22 and the depth of the third grooves 23 are same. By defining grooves with same structures on the first protective layers 20 and the second protective layer 30, same film thicknesses of layers can be configured on the first protective layer 20 and the second protective layer 30. Therefore, the difference in the film thicknesses of the first protective layer 20 and the second protective layer 30 can be balanced, and the first protective layer 20 and the second protective layer 30's effect of effectively blocking water and oxygen can be ensured, while an overall thickness of the quantum dot film 100 is minimized as much as possible.

In this embodiment, by defining the second grooves 22 and the third grooves 23, two protruding structures 13 are formed on the quantum dot layers 10. The existence of the protruding structures 13 makes height differences form on the upper sides and the lower sides of the quantum dot layers 10. Therefore, the optical paths of the lights passing through the quantum dot layers 10 are similar or equal, so that levels of excitation by the quantum dots 12 are similar or same, thereby allowing light extraction from the quantum dot film 100 at different viewing angles to be more uniform. For other descriptions please refer to the above-mentioned embodiments, and redundant description will not be mentioned herein again.

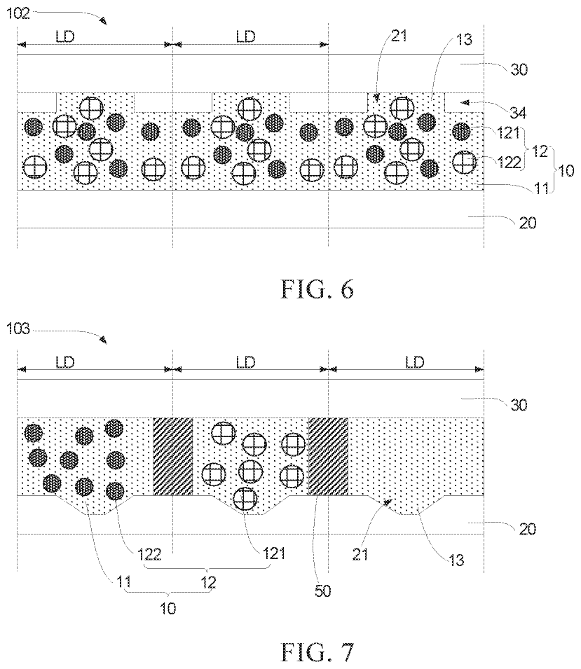

In one embodiment, please refer to FIG. 6. FIG. 6 is a schematic diagram of yet another cross-sectional structure of the quantum dot film provided by one embodiment of the present disclosure. The difference from the aforesaid embodiments is that a quantum dot film 102 includes the quantum dot layers 10 and the first protective layer 20 and the second protective layer 30 located on opposite sides of the quantum dot layers 10; in each quantum dot region LD, the quantum dot layers 10 have the protruding structures 13 to make height differences to form between the quantum dot layers 10; and there are gaps formed between the quantum dot layers 10 and the first protective layer 20 or the second protective layer 30. That is, surfaces of the first protective layer 20 and the second protective layer 30 are flat, and no grooves are defined, and due to the existence of the protruding structures 13, gaps are formed between the quantum dot layers 10 and the first protective layer 20 or the second protective layer 30.

Specifically, as illustrated in FIG. 6, the gaps 34 are formed between the quantum dot layers 10 and the second protective layer 30. Of course, in order to avoid failure of the quantum dots 12 of the quantum dot layers 10, water and oxygen are not allowed in the gaps 34. Therefore, when the second protective layer 30 is disposed on the quantum dot layers 10, it needs to be performed under specific process conditions, for example, it can be performed in a vacuum-dried environment.

Furthermore, the cross-sectional shape of the protruding sections 13 is rectangular. Of course, the present disclosure is not limited thereto. The cross-sectional shape of the protruding structures 13 further includes any one of arc, triangular, trapezoidal, etc., or one of other irregular shapes. In this embodiment, the cross-sectional shape being rectangular is used as an example for description. Furthermore, existence of the protruding structures 13 allows height differences to form between the quantum dot layers 10, thereby reducing optical path differences of lights passing through the quantum dot layers 10, making levels of excitation by the quantum dots 12 similar or same.

Optionally, concentrations of the quantum dots 12 of the quantum dot layers 10 are different, and the concentrations of the quantum dots 12 are in positive correlation with heights of the quantum dot layers 10. Wherein, the positive correlation means that the concentration of the quantum dots 12 increases as the heights of the quantum dot layers 10 increase. Specifically, the concentrations of the quantum dots 12 at the region corresponding to the quantum dot layers 10 where the protruding structures 13 are formed are relatively high; and the concentrations of the quantum dots 12 at the region corresponding to the quantum dot layers 10 where the protruding structures 13 are not formed are relatively low. Furthermore, the concentrations of the quantum dots 12 are related to how much light of other colors is generated by light passing through the quantum dot layers 10 and excited. Therefore, by configuring different concentrations of the quantum dots 12 in different regions, levels of excitation of the light passing through the quantum dot layers 10 can be further improved, and light extraction of the quantum dot film 100 can be more uniform at different viewing angles.

In this embodiment, by disposing the protruding structures 13 on the quantum dot layers 10, height differences are formed between the quantum dot layers 10. Therefore, the optical paths of the lights passing through the quantum dot layers 10 are similar or equal, so that levels of excitation by the quantum dots 12 are similar or same, thereby allowing light extraction from the quantum dot film 100 at different viewing angles to be more uniform. For other descriptions please refer to the above-mentioned embodiments, and redundant description will not be mentioned herein again.

In one embodiment, please refer to FIG. 7. FIG. 7 is a schematic diagram of still another cross-sectional structure of the quantum dot film provided by one embodiment of the present disclosure. The difference from the aforesaid embodiments is that a quantum dot film 103 includes the quantum dot layers 10, the first protective layer 20 and the second protective layer 30 located on opposite sides of the quantum dot layers 10, and black matrices 50 dividing the quantum dot layers 10 into the plurality of quantum dot regions LD; the quantum dots 12 of every two adjacent quantum dot regions LD are different; and in each of the quantum dot regions LD, height differences are present between the quantum dot layers 10.

Specifically, as illustrated in FIG. 7, in each the corresponding quantum dot region LD, first grooves 21 are defined on the first protection layer 20, and a cross-sectional shape of the first grooves 21 is trapezoidal. Of course, the cross-sectional shape of the first grooves 21 of the present disclosure further includes any one of rectangular, triangular, or arc, or one of other irregular shapes. In this embodiment, the cross-sectional shape being trapezoidal is used as an example for description. The quantum dot layers 10 are filled in the first grooves to form the protruding structures 13, and then the cross-sectional shape of the protruding structures 13 is also trapezoidal. It can be understood that the quantum dot layers 10 are filled in the first grooves 21 to form the protruding structures 13, and then the cross-sectional shape of the protruding structures 13 is same as the cross-sectional shape of the first grooves 21. Furthermore, existence of the protruding structures 13 allows height differences to form between the quantum dot layers 10, thereby reducing optical path differences of lights passing through the quantum dot layers 10.

Furthermore, the black matrices 50 divide the quantum dot layers 10 into the plurality of quantum dot regions LD; the quantum dots 12 of every two adjacent quantum dot regions LD are different; every three adjacent quantum dot regions LD compose one light extraction unit; and the plurality of light extraction units are arranged cyclically. For example, the quantum dots 12 of the first quantum dot region LD are red quantum dots 121; the quantum dots 12 of the second quantum dot region LD are green quantum dots 122; and the quantum dots 12 of the third quantum dot region LD are blue quantum dots, or no quantum dot is disposed, so blue light sources are used for the excited light sources 40. The black matrices 50 are disposed between different quantum dot regions LD and are configured to block light leakage to prevent light crosstalk between adjacent quantum dot regions LD.

One embodiment of the present disclosure further provides a display panel. The display panel includes the quantum dot film of one of the aforesaid embodiments and the plurality of excited light sources. Each quantum dot region corresponds to one of the excited light sources.

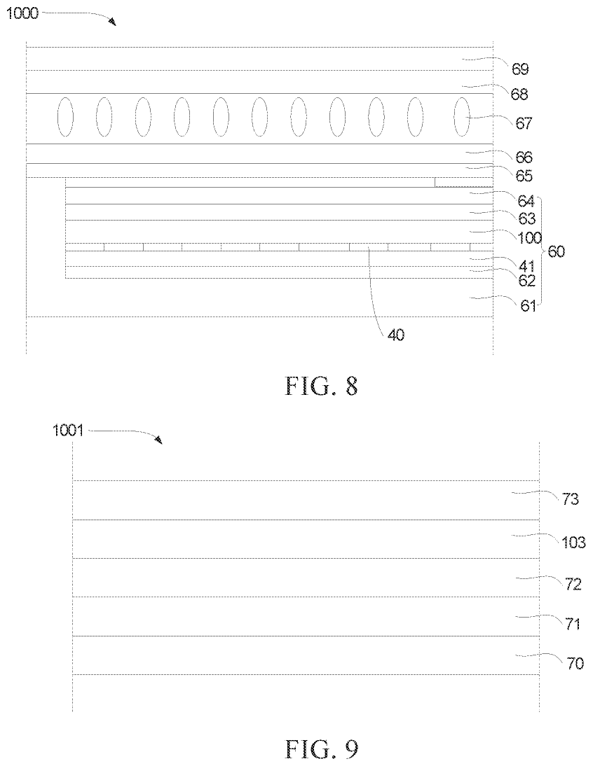

In one embodiment, please refer to FIG. 8. FIG. 8 is a schematic diagram of a cross-sectional structure of the display panel provided by one embodiment of the present disclosure. The display panel is a liquid crystal display (LCD) panel. The liquid crystal display panel 1000 includes a backlight module 60, a lower polarizer sheet 65, an array substrate 66, a liquid crystal layer 67, a color film substrate 68, and an upper polarizer sheet 69 from bottom to top.

A direct-lit backlight is used in the backlight module 60. The backlight module 60 includes a backplate 61 and a reflective sheet 62, the excited light sources 40, the quantum dot film 100, a diffusion sheet 63, and an optical diaphragm 64, etc., which are sequentially disposed in an accommodation space formed by the backplate 61. Wherein, the excited light sources 40 include blue light LED chips. The blue light LED chips are arranged on a light plate 41 in an array manner to provide backlight to the liquid crystal display panel 1000. The quantum dot film illustrated in FIG. 8 only takes the quantum dot film 100 in the aforesaid embodiment as an example. The quantum dot film of the liquid crystal display panel 1000 includes the quantum dot film 101 or the quantum dot film 102 of the aforesaid embodiments.

In one embodiment, please refer to FIG. 9. FIG. 9 is a schematic diagram of another cross-sectional structure of the display panel provided by one embodiment of the present disclosure. The display panel is a quantum dot light emitting diode (QLED) display panel. From bottom to top, the QLED display panel 1001 sequentially includes a base substrate 70, a driving circuit layer 71, a light emitting functional layer 72, the quantum dot film 103, and an encapsulation layer 73, etc. Wherein, the light emitting functional layer 72 includes excited light sources. The excited light sources include blue light LED chips. The quantum dot film includes the quantum dot film 103 of the aforesaid embodiments. Of course, the QLED display panel 1001 can further include a color filter sheet disposed on the encapsulation layer 73. At this time, the quantum dot film can include the quantum dot film 100, the quantum dot film 101, or the quantum dot film 102 of the aforesaid embodiments.

One embodiment of the present disclosure provides a display device, which includes the display panel of one of the aforesaid embodiments, circuit boards, other devices bound to the display panel, and cover plates covering the display panel, etc.

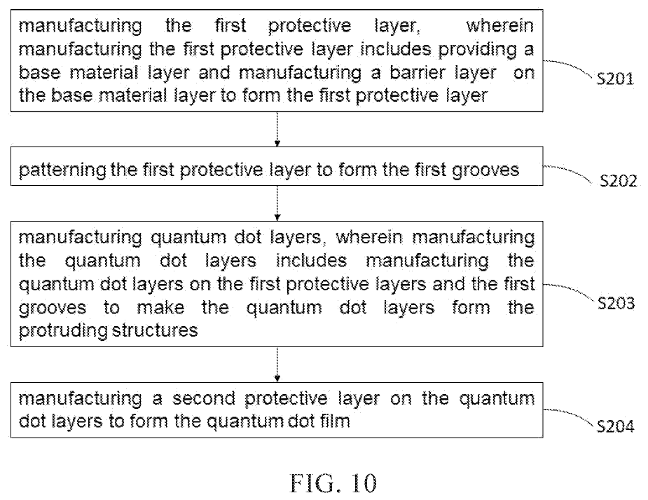

One embodiment of the present disclosure further provides a manufacturing method of the quantum dot film. Please refer to FIG. 1 and FIG. 10 at the same time. FIG. 10 is a flowchart of the manufacturing method of the quantum dot film provided by one embodiment of the present disclosure. The manufacturing method of the quantum dot film includes following steps.

S201: manufacturing the first protective layer 20, wherein manufacturing the first protective layer includes providing a base material layer 31 and manufacturing a barrier layer 32 on the base material layer 31 to form the first protective layer 20.

Specifically, the base material layer 31 includes polyethylene terephthalate, etc., and a layer of an inorganic thin film is deposited on the base material layer 31 to act as the barrier layer 32 by using deposition processes such as chemical vapor deposition (CVD) method, plasma enhance chemical vapor deposition (PECVD) method, atomic layer deposition (ALD) method, etc. A material of the inorganic thin film includes at least one of aluminum nitride, aluminum oxynitride, titanium nitride, titanium oxynitride, zirconium nitride, zirconium oxynitride, silicon oxide, silicon nitride, silicon oxynitride, graphene, etc. The inorganic thin film can effectively block moisture and oxygen from intruding into the quantum dot layers 10.

S202: patterning the first protective layer 20 to form the first grooves 21.

Specifically, the first protective layer 20 is divided into a plurality of partitions, the first grooves 21 are manufactured by photo processes in each of the partitions, and the cross-sectional shape of the first grooves 21 is arc.

S203: manufacturing quantum dot layers 10, wherein manufacturing the quantum dot layers 10 includes manufacturing the quantum dot layers 10 on the first protective layers 20 and the first grooves 21 to make the quantum dot layers 10 form the protruding structures 13.

Specifically, the quantum dots 12 are dispersed in a macromolecule polymer solution to form a quantum dot glue solution. Optionally, the quantum dots 12 include the red quantum dots 121 and the green quantum dots 122, and the macromolecule polymer solution is formed by doping macromolecule polymer in an organic solvent. The macromolecule polymer includes one or more of macromolecule polymers such as silicone resin, epoxy resin, polyacrylamide, acrylic resin, photocuring resin, heat curing resin, etc.

By spraying the quantum dot glue solution on the first protective layer 20 and the first grooves 21 by a spraying process and then performing a pre-curing process on the sprayed quantum dot glue solution, the quantum dot layers 10 are formed.

Specifically, the pre-curing process can be cured by irradiation of ultraviolet light, heating, evaporating solvent, or adding curing agent. For example, when the macromolecule polymer solution is epoxy resin, the quantum dot glue solution is generally cured by adding acid anhydride agents, acid agents, or amine curing agents. When the macromolecule polymer solution is acrylic resin, the quantum dot glue solution is generally cured by irradiation of ultraviolet light or heating.

S204: manufacturing a second protective layer 30 on the quantum dot layers 10 to form the quantum dot film 100.

Specifically, the base material layer 31 and the barrier layer 32 are sequentially manufactured on the quantum dot layers 10 to form the second protective layer 30, and then curing is performed on the quantum dot layers 10.

According to the above-mentioned embodiments:

In the quantum dot film, the manufacturing method thereof, and the display panel provided by the present disclosure, the quantum dot film are divided into the plurality of quantum dot regions; the quantum dot film includes the quantum dot layers and the first protective layer and the second protective layer disposed on two opposite sides of the quantum dot layers; the grooves are defined on the first protective layer and/or the second protective layer corresponding to each quantum dot region; and the quantum dot layers are filled in the grooves to form the protruding structures.

Therefore, the quantum dot layers of each quantum dot region are made to have height differences to reduce optical path differences of different lights at different angles passing through the quantum dot layers, and extents of the lights of different angles passing through the quantum dot layers undergo similar levels of excitation, which prevents occurrences of uneven display.

In the above-mentioned embodiments, the description of each embodiment has its emphasis, and for some embodiments that may not be detailed, reference may be made to the relevant description of other embodiments.

The embodiments of present disclosure are described in detail above. This article uses specific cases for describing the principles and the embodiments of the present disclosure, and the description of the embodiments mentioned above is only for helping to understand the method and the core idea of the present disclosure. It should be understood by those skilled in the art, that it can perform changes in the technical solution of the embodiments mentioned above, or can perform equivalent replacements in part of technical characteristics, and the changes or replacements do not make the essence of the corresponding technical solution depart from the scope of the technical solution of each embodiment of the present disclosure.

1. A quantum dot film divided into a plurality of quantum dot regions, comprising:
quantum dot layers, wherein quantum dots are disposed on the quantum dot layers; and
a first protective layer and a second protective layer disposed on two opposite sides of the quantum dot layers;
wherein the quantum dot layers of each of the quantum dot regions have height differences to reduce optical path differences between lights of different incident angles passing through the quantum dot layers.

2. The quantum dot film as claimed in claim 1, wherein the quantum dot layers of the quantum dot regions have protruding structures.

3. The quantum dot film as claimed in claim 2, wherein first grooves are defined on one of the first protective layer or the second protective layer corresponding to the quantum dot regions, and the protruding structures are filled in the first grooves.

4. The quantum dot film as claimed in claim 2, wherein second grooves and third grooves are defined where the first protective layer and the second protective layer correspond to the quantum dot regions, and the protruding structures are filled in the second grooves and the third grooves.

5. The quantum dot film as claimed in claim 4, wherein the second grooves are defined opposite to the third grooves.

6. The quantum dot film as claimed in claim 4, wherein a sum of a depth of the second grooves and a depth of the third grooves is equal to a separation distance between the first protective layer and the second protective layer.

7. The quantum dot film as claimed in claim 6, wherein the depth of the second grooves is equal to the depth of the third grooves.

8. The quantum dot film as claimed in claim 2, wherein a gap is formed between part of the quantum dot layers in the quantum dot regions and one of the first protective layer or the second protective layer.

9. The quantum dot film as claimed in claim 2, wherein a shape of a cross section of the protruding structures comprises rectangular, arc, triangular, or trapezoidal.

10. The quantum dot film as claimed in claim 1, wherein the quantum dots of different quantum dot regions are same, and the quantum dots comprise red quantum dots and green quantum dots.

11. The quantum dot film as claimed in claim 10, wherein a particle size of the red quantum dots is larger than a particle size of the green quantum dots.

12. The quantum dot film as claimed in claim 10, wherein concentrations of the quantum dots are in positive correlation with heights of the quantum dot layers.

13. The quantum dot film as claimed in claim 1, wherein the quantum dot film further comprises black matrices, the quantum dot layers are divided into the plurality of quantum dot regions by the black matrices, and the quantum dots in each two adjacent quantum dot regions are different.

14. A display panel, comprising a quantum dot film and a plurality of excited light sources, wherein the quantum dot film is divided into a plurality of quantum dot regions, each of the quantum dot regions corresponds to one of the excited light sources, and the quantum dot film comprises:
quantum dot layers, wherein quantum dots are disposed on the quantum dot layers; and
a first protective layer and a second protective layer disposed on two opposite sides of the quantum dot layers;
wherein the quantum dot layers of each of the quantum dot regions have height differences to reduce optical path differences between lights of different incident angles passing through the quantum dot layers.

15. The display panel as claimed in claim 14, wherein the quantum dot layers of the quantum dot regions have protruding structures.

16. The display panel as claimed in claim 15, wherein a shape of a cross section of the protruding structures comprises rectangular, arc, triangular, or trapezoidal.

17. The display panel as claimed in claim 14, wherein the excited light sources are blue light emitting diodes (LEDs).

18. A manufacturing method of a quantum dot film, comprising:
manufacturing a first protective layer, wherein manufacturing the first protective layer comprises providing a base material layer and manufacturing a barrier layer on the base material layer to form the first protective layer;
patterning the first protective layer to form first grooves;
manufacturing quantum dot layers, wherein manufacturing the quantum dot layers comprises manufacturing the quantum dot layers on the first protective layer and the first grooves to make the quantum dot layers form protruding structures; and
manufacturing a second protective layer on the quantum dot layers to form the quantum dot film.

19. The manufacturing method of the quantum dot film as claimed in claim 18, wherein the step of manufacturing the quantum dot layers on the first protective layer and the first grooves to make the quantum dot layers form the protruding structures further comprises:
dispersing quantum dots in a macromolecule polymer solution to form a quantum dot glue solution;
spraying the quantum dot glue solution on the first protective layer and the first grooves by a spraying process; and
performing a pre-curing process on the sprayed quantum dot glue solution to form the quantum dot layers.

20. The manufacturing method of the quantum dot film as claimed in claim 19, wherein ultraviolet light irradiation, heating, evaporating solvents, or adding curing agent is adopted in the pre-curing process.
